(19) United States
(12) Patent Application Publication
(10) Pub. No.: US 2023/0327397 A1
(43) Pub. Date: Oct. 12, 2023

(54) LASER DIODE WITH INTEGRATED THERMAL SCREEN

(71) Applicant: FERDINAND-BRAUN-INSTITUT GGMBH, LEIBNIZ-INSTITUT FÜR HÖCHSTFREQUENZTECHNIK, Berlin (DE)

(72) Inventors: Pietro DELLA CASA, Berlin (DE); Paul CRUMP, Berlin (DE); Mohamed ELATTAR, Berlin (DE); Matthias M. KAROW, Berlin (DE)

(21) Appl. No.: 18/334,203

(22) Filed: Jun. 13, 2023

Related U.S. Application Data
(63) Continuation of application No. PCT/EP2021/085730, filed on Dec. 14, 2021.

(30) Foreign Application Priority Data
Dec. 14, 2020 (DE) 10 2020 133 368.4

(51) Int. Cl. H01S 5/024; H01S 5/30

(52) U.S. Cl. CPC H01S 5/02461; H01S 5/02469; H01S 5/3054; H01S 5/2036

(57) ABSTRACT

The present invention relates to a diode laser with an integrated thermal aperture. A laser diode (10) according to the invention comprises an active layer (14) formed between an n-doped semiconductor material (12) and a p-doped semiconductor material (16), wherein the active layer (14) forms an active zone (40) with a width w along a longitudinal axis for generating electromagnetic radiation; wherein in the p-doped semiconductor material (16) and/or in the n-doped semiconductor material (12) a thermal aperture (18) formed in a layer shape with a thermal conductivity coefficient k_{block} smaller than a thermal conductivity coefficient k_{bulk} of the corresponding semiconductor material (16, 12) is formed for a spatially selective heat transport from the active zone (40) to a side of the corresponding semiconductor material (16, 12) opposite to the active layer (14).

### CROSS-REFERENCE TO RELATED APPLICATION(S)

This application is a continuation of PCT international application no. PCT/EP2021/085730 filed on Dec. 14, 2021, which claims priority to German patent application no. DE 10 2020 133 368.4 filed on Dec. 14, 2020, each of which is incorporated by reference herein in its entirety.

### TECHNICAL FIELD

The present invention relates to a laser diode with an integrated thermal aperture.

### BACKGROUND

Broad-area diode lasers (BALs) can exhibit particularly high efficiency and brilliance. With these emitters, output powers of >15 W can be reliably achieved. BALs are the most efficient light source for near-infrared (NIR) radiation, so they are widely used as pump sources for solid-state and fiber lasers. They are also the key element of fiber coupled laser systems designed to deliver beams of high radiance for materials processing at high wall-plug efficiencies. To increase the output power of these systems and reduce their cost, it is important to improve the beam quality of the slow axis, as this enables the coupling of a larger number of emitters in low numerical aperture (NA) fibers.

However, at high optical output powers and the associated operating currents, there is generally a significant degradation of beam quality, which has a particularly negative effect on coupling in fibers. It has been shown that the thermal lens (rather than charge carrier or gain induced guiding) in the slow axis is one of the predominant causes of beam quality degradation at increased operating current (Bai, J. G. et al, Mitigation of Thermal Lensing Effect as a Brightness Limitation of High-Power Broad Area Diode Lasers, Proc. SPIE 7953, 79531F (2011)). Thus, the decisive factor for the degradation of beam quality at high output powers is the formation of a lateral temperature gradient due to a temperature increase in the central region under the laser stripe, which leads to a local increase of the refractive index and thus to additional lateral waveguiding and, as a consequence, to a larger divergence angle.

In particular, to improve the heat transport, an extension of the laser resonator or an influencing of the thermal flow between laser diode and submount (heat path technique; see, e.g., Bai et al., DE 10 2013 114 226 B4 and US 2016 0315 446 A1) have been proposed. This can reduce the lateral temperature gradient and thus flatten the generated thermal lens. However, diode lasers with longer resonators have higher manufacturing costs. Recently, however, it has been shown that a high thermal barrier is formed at the interface between the laser diode and an appropriate metallization, which significantly reduces the effectiveness of the thermal path technique on the thermal lens (Rieprich, J. et al, Chip-carrier thermal barrier and its impact on lateral thermal lens profile and beam parameter product in high power broad area lasers, J. Appl. Phys. 123, 125703 (2018)).

Another way to reduce the lateral temperature gradient is to additionally heat the laser diode with an external heat source (Hohimer, J. P., Mode control in broad area diode lasers by thermally induced lateral index tailoring, Appl. Opt. Phys. Lett. 52, 260 (1988)). However, the integration of an external heat source into a diode laser is very complex and therefore not very practical.

A reduction of the lateral temperature gradient can also be achieved via a specially adapted layer structure (Winterfeldt, M. et al, Assessing the Influence of the Vertical Epitaxial Layer Design on the Lateral Beam Quality of High-Power Broad Area Diode Lasers, Proc. SPIE 9733, 97330O (2016)). However, such an adjustment can only marginally improve the lateral beam quality. Moreover, such adjustments are only possible with certain laser designs.

### SUMMARY

It is therefore an object of the present invention to provide a laser diode in which the lateral temperature gradient can be reduced and the generated thermal lens can be flattened. In particular, the laser diode should not require any external heat source or adjustments in the layer structure external to the chip (e.g., metallization), i.e., based only on monolithically integrated structures within the diode lasers.

These objects are achieved according to the invention by the features of patent claim 1. Expedient embodiments of the invention are included in the respective dependent claims.

A laser diode according to the invention comprises an active layer formed between an n-doped semiconductor material and a p-doped semiconductor material, the active layer forming along a longitudinal axis an active zone with a width w for generating electromagnetic radiation; wherein in the p-doped semiconductor material a thermal aperture formed in a layer shape with a thermal conductivity coefficient k_{block} smaller than a thermal conductivity coefficient k_{bulk} of the p-doped semiconductor material (for example in the p-doped semiconductor material between the active zone and a cooled underside of the laser diode) is formed for spatially selective heat transport from the active zone to a side of the p-doped semiconductor material opposite to the active layer; or a thermal aperture formed in a layer shape with a thermal conductivity coefficient k_{block} smaller than a thermal conductivity coefficient k_{bulk} of the n-doped semiconductor material is formed in the n-doped semiconductor material for spatially selective heat transport from the active zone to a side of the n-doped semiconductor material opposite to the active layer.

A thermal aperture according to the invention can thus be formed both in the p-doped semiconductor material and in the n-doped semiconductor material, with formation preferably taking place within the corresponding semiconductor material. In the following, a p-side thermal aperture is assumed as an example, but the explanations apply accordingly to an n-side thermal aperture.

A laser diode is understood to be a layer structure consisting of a semiconductor material with or without metallization (so-called laser chip). The term semiconductor material is used here generically to designate any semiconductor material or a combination of semiconductor materials, for example a combination of the AlInGaAsNSb material system. In particular, the n-doped semiconductor material and the p-doped semiconductor material may also each comprise layer systems of corresponding semiconductor materials of different types or different doping levels in different compositions. The use is thus to be understood as synonymous with the terms n-side semiconductor material and p-side semiconductor material.

An active layer is formed at the transition region between the n-doped and the p-doped semiconductor material. The generation of electromagnetic radiation takes place in the electrically pumped region of the active layer within the active zone. A large part of the heat generated during operation of the laser diode is generated there, which must be dissipated accordingly. This can be done in particular via a submount, whereby the submount can be thermally conductively connected to the underside of the laser diode below the active zone, for example. The connection between the underside of the laser diode and the submount is state of the art and can be made in particular by soldering or gluing.

According to the invention, a thermal aperture formed in a layer shape with a thermal conductivity coefficient k_{block} smaller than a thermal conductivity coefficient k_{bulk} of the surrounding p-doped semiconductor material is formed in the p-doped semiconductor material below the active zone for spatially selective heat transport from the active zone to the underside of the laser diode. The thermal conductivity coefficient (also referred to as thermal conductivity or thermal conductivity coefficient) determines the heat flow through a material based on thermal conduction. The lower this value, the worse the thermal conductivity properties of a material. According to the invention, a thermal aperture is intended to reduce the lateral temperature gradients (i.e., flatten the thermal lens) by counteracting a spatial lateral widening of the heat flow in the region between the active zone and the underside of the laser diode by locally increasing the thermal resistance in the conventional widening region (laterally below the active zone) in the lateral direction. As a result of increased thermal resistance thereof, the local temperature of the side regions (the thermal aperture) increases as more heat is generated within the stripe (in the central region) with increasing output power. This corresponds to a lower thermal gradient between the central region and the side regions and thus a flatter thermal lens.

With regard to the relationship between the two thermal conductivity coefficients, the thermal conductivity coefficient k_{bulk} of the p-doped semiconductor material below the active zone is particularly important. In the case of a p-doped semiconductor material composed of several layers, the individual layers may each have slightly different thermal conductivity coefficients k_{layer}. The thermal conductivity coefficient k_{bulk} can then be regarded as the resulting thermal conductivity coefficient of all layers involved in the heat flow. As an approximation, an average thermal conductivity coefficient of the p-doped semiconductor material below the active zone can also be used for the thermal conductivity coefficient k_{bulk} of the p-doped semiconductor material. Alternatively, as an approximation, the thermal conductivity coefficient k_{bulk} of the p-doped semiconductor material can also be equated with the thermal conductivity coefficient k_{KS} of a p-contact layer of the p-doped semiconductor material.

Thus, the idea of the present invention is particularly to realize a flat thermal lens by integrating a monolithically integrated thermal aperture (internal thermal path technique) directly into the laser diode. In contrast, external thermal path techniques are less effective due to the presence of the intrinsic semiconductor-metal thermal barrier. A thermal aperture according to the invention can also be placed very close to the active zone, minimizing the widening of the heat flow in the lateral direction, resulting in a particularly flat thermal lens. The heat path technique known from the prior art can thus be applied within the laser diode, significantly increasing its effectiveness and efficiency.

Preferably, the thermal aperture consists of a semiconductor material. This should have a particularly low thermal conductivity (for a low thermal conductivity coefficient k_{block}). In addition, a high electrical conductivity is preferred. In particular, the thermal aperture can be constructed from the same semiconductor material system as the p-doped semiconductor material (e.g., in the case of an AlInGaAsP composite on a GaAs substrate: GaAs and AlGaAs as p-semiconductor material). The thermal conductivity coefficient k_{block} can be lowered by changing the indium and/or phosphorus content (e.g., in the case of an AlInGaAsP composite on a GaAs substrate: GaAs and AlGaAs as p-type semiconductor material, InGaP or InGaAsP as thermal aperture).

Preferably, to achieve particularly small thermal conductivity coefficients k_{block}, the thermal aperture is formed of periodically alternating materials (for example, different semiconductors or semiconductors and air), with high numbers of regular alternations between the materials, forming many interfaces with large differences in thermal conductivity k_{layer}. Heat transport across interfaces is limited, bringing an additional reduction in thermal conductivity k_{block} (see J. Piprek et al, Thermal conductivity reduction in GaAs—AlAs distributed Bragg reflectors, in IEEE Photon. Tech. Lett. 10, 81(1998)).

Preferably, the thermal aperture can be realized with a photonic crystal structure. A photonic crystal structure is understood to be 3-D periodic nanostructures which can influence the movement of photons within the crystal lattice. Typically, to generate a high refractive index contrast, openings (“air holes”) filled with air or other particularly low refractive index material are formed in the structures. These openings and the multiple material transitions are responsible for a particularly high reduction in thermal conductivity in these materials. In summary, phonic crystal structures can be used to create regions with good optical properties and very low thermal conductivity. The same applies to 1-D periodic lattices (superlattices), in which thin layers of two different materials and, in particular, semiconductor materials are arranged alternately on top of each other.

With a laser diode according to the invention, the optical properties of the region below the active zone can thus be largely maintained despite an additional thermal aperture.

For example, for laser diodes based on GaAs (k_{KS}≈44 W/(m·K)) or AlₓGa₁₋ₓAs (k_{KS}≈11-91 W/(m·K)), a thermal aperture of InGaP (k_{block}≈5 W/(m·K)), InGaAsP (k_{block}≈5 W/(m·K)), InGaAsSb, or an InGaP—InGaAsP superlattice (k_{block}≈2.5 W/(m·K)) can be constructed.

For a sufficient aperture effect, the thermal conductivity coefficient k_{block} should be as low as possible. The thermal conductivity coefficient k_{block} should preferably be at most 30%, more preferably at most 10%, more preferably at most 5% and especially preferably at most 1% of the corresponding bulk value k_{bulk}. With a InGaP—InGaAsP superlattice, a thermal conductivity coefficient k_{block} can be achieved, which is about half the values for the thermal conductivity coefficient k of InGaP and InGaAsP (see J. Piprek et al., Thermal conductivity reduction in GaAs—AlAs distributed Bragg reflectors, in IEEE Photon. Tech. Lett. 10, 81(1998)). However, much lower thermal conductivities can be realized by photonic crystal structures.

Preferably, the thermal aperture forms a gap-shaped passage region arranged parallel to the active layer for a heat flow directed from the active zone towards an outer side (e.g., a p-side underside provided with a heat sink in the case of a p-side thermal aperture) of the laser diode. In such an arrangement, the thermal aperture can restrict the heat flow along the entire resonator axis (z-axis) to a slit-shaped passage. A centrally symmetrical arrangement of the slit-shaped passage region with respect to the active zone (medial arrangement) is preferred for efficiency reasons.

Preferably, the lateral distance dx between an outer edge of the active zone (lateral boundary in lateral direction) and a nearest inner edge of the thermal aperture (lateral boundary in lateral direction directed to the active zone) is −w/6≤dx≤+w/6. This means that the distance preferably depends on the width w of the active zone and is chosen such that the inner edge of the thermal aperture can have both a positive and a negative lateral distance to the outer edge of the active zone. Especially preferred is a distance dx of 0, i.e., when the outer edge of the active zone and the corresponding inner edge of the thermal aperture coincide spatially when projected on the underside of the laser diode.

Preferably, the vertical distance dy between the center of the active layer and the top of the thermal aperture is 0 μm≤dy≤1 μm. This means that the top of the thermal aperture is preferably located immediately below the center of the active layer and at most 1 μm away from it. The smallest possible distance has the highest aperture effect, but can have a negative effect on the optical properties. At a distance greater than 1 μm, the lateral widening of the heat flow may no longer be effectively suppressed.

Preferably, the thermal aperture has an aperture thickness d_{block} of between 0.3 μm and 3 μm. A thicker thermal aperture can provide greater suppression of the lateral widening of the heat flow.

Preferably, the p-doped semiconductor material (with integrated thermal aperture) has a total layer thickness d between 0.5 μm and 10 μm, more preferably between 1 μm and 5 μm, even more preferably between 2 μm and 3 μm.

Preferably, a thermal aperture formed in a layer shape is formed in the n-doped semiconductor material and a thermal aperture formed in a layer shape is formed in the p-doped semiconductor material. The thermal aperture in the n-doped semiconductor material may functionally correspond to the thermal aperture in the p-doped semiconductor material. In this respect, all the information provided on the thermal aperture in the p-doped semiconductor material in this description applies accordingly, taking into account the change in doping. Preferably, the thermal aperture in the n-doped semiconductor material and the thermal aperture in the p-doped semiconductor material can be constructed symmetrically with respect to the active layer. This symmetry may refer in particular to the geometrical and/or material formation of the thermal apertures. However, the formation of the thermal apertures may also differ, for example if the p-doped semiconductor material and the n-doped semiconductor material have different thicknesses and an adjustment of the distances is required. Such an embodiment is advantageous when the laser diode is mounted for double-sided cooling, i.e., when heat extraction can be performed to both sides of the laser diode.

Further preferred embodiments of the invention result from the features mentioned in the dependent claims.

The various embodiments of the invention mentioned in this application can be advantageously combined with each other, unless otherwise specified in the individual case.

### BRIEF DESCRIPTION OF THE DRAWINGS

The invention is explained below in embodiment examples with reference to the accompanying drawing, wherein:

FIG. 1 is a schematic illustration of an exemplary conventional laser diode without thermal aperture,

FIG. 2 is a schematic illustration of an exemplary first embodiment of a laser diode according to the invention with thermal aperture,

FIG. 3 is a simulation of the temperature as a function of the lateral position (x-axis) within the active zone,

FIG. 4 is a simulation of the normalized thermal lens curvature factor |B2| as a function of the thermal conductivity coefficient k_{KS} of the p contact layer,

FIG. 5 is a simulation of the normalized thermal lens curvature factor |B2| as a function of the aperture thickness d_{block},

FIG. 6 is a simulation of the normalized thermal lens curvature factor |B2| as a function of the lateral distance dx,

FIG. 7 is simulation of the temperature difference ΔT between the temperature T as a function of lateral position (x-axis) and the peak temperature Tₚₑₐₖ at the position x=0 for structures with the KS material according to FIG. 4, and

FIG. 8 is a schematic illustration of an exemplary second embodiment of a laser diode according to the invention with two thermal apertures.

### DETAILED DESCRIPTION

### LIST OF REFERENCE NUMERALS

10 Laser diode

12 n-doped semiconductor material

14 Active layer

16 p-doped semiconductor material

18 Thermal aperture

20 Solder layer

30 Submount

30a First submount

30b Second submount

40 Active zone

42 Heat flow

dx Lateral distance (slow axis)

dy Vertical distance (fast axis)

d_{block} Aperture thickness

w Width

### Description

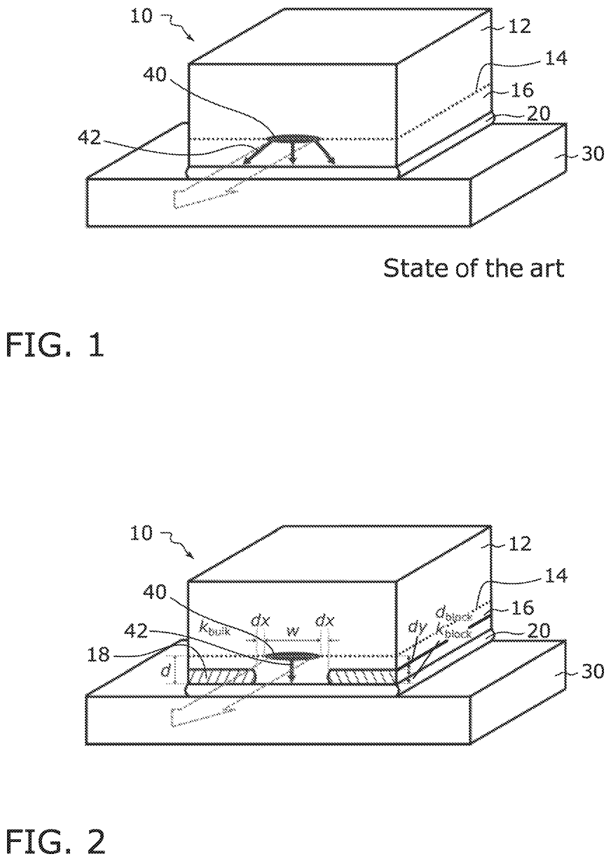

FIG. 1 shows a schematic illustration of an exemplary conventional laser diode without thermal aperture. The diode laser shown comprises a laser diode 10 having an active layer 14 formed between an n-doped semiconductor material 12 and a p-doped semiconductor material 16, the active layer 14 forming along a longitudinal axis an active zone 40 having a width w for generation of electromagnetic radiation; and a submount 30, wherein the submount 30 is thermally conductively connected to the p-side underside of the laser diode 10 below the active zone 40. The thermally conductive connection may be formed by an intermediate solder layer 20, wherein the solder is intended to provide optimal heat transfer between the underside of the laser diode 10 and the submount 30.

In particular, the laser diode 10 may have a multilayer structure comprising an n-substrate, an n-cladding layer overlying the n-substrate, an n-waveguide layer overlying the n-cladding layer, an active layer 14 overlying the n-waveguide layer, a p-waveguide layer overlying the active layer 14, a p-cladding layer overlying the p-waveguide layer, a p-contact layer overlying the p-cladding layer, and a metallic p-contact overlying the p-contact layer.

The losses occurring as heat during operation of the laser diode in the active zone 40 must be dissipated from the active zone 40. For this purpose, a submount 30 is usually used as a corresponding heat sink. However, the heat flow directed from the active zone 40 to the submount 30 spreads out strongly in the lateral direction and leads to an inhomogeneous temperature distribution in the region below the active zone 40. The resulting temperature distribution can then have thermo-optical effects on the generated electromagnetic radiation and, by forming a thermal lens in this region, contribute to a deterioration of the beam quality during radiation emission.

FIG. 2 shows a schematic illustration of an exemplary first embodiment of a laser diode with thermal aperture according to the invention. The diode laser shown comprises a laser diode 10 with an active layer 14 formed between an n-doped semiconductor material 12 and a p-doped semiconductor material 16, the active layer 14 forming along a longitudinal axis (longitudinal direction, z-axis) an active zone 40 with a width w for generating electromagnetic radiation; and a submount 30, wherein the submount 30 below the active zone 40 is thermally conductively connected to the p-side underside of the laser diode 10. This corresponds as far as possible to the structure described for FIG. 1.

In the p-doped semiconductor material 16, however, a thermal aperture 18 formed in a layer shape with a thermal conductivity coefficient k_{block} smaller than a thermal conductivity coefficient k_{bulk} of the p-doped semiconductor material 16 (below the active zone 40) is formed for a spatially selective heat transport from the active zone 40 to the side of the p-doped semiconductor material 16 opposite to the active layer 14 (underside of the laser diode 10) and thus to the submount 30. As an approximation, an average thermal conductivity coefficient of the p-doped semiconductor material 16 can also be used for the thermal conductivity coefficient k_{bulk} of the p-doped semiconductor material below the active zone 40. Alternatively, the thermal conductivity coefficient k_{bulk} of the p-doped semiconductor material 16 can also be approximately equated with the thermal conductivity coefficient k_{KS} of a p-contact layer of the p-doped semiconductor material 16.

Here, too, the thermally conductive connection can be formed by an intermediate solder layer 20, the solder being intended to enable optimum heat transfer between the underside of the laser diode 10 and the submount 30. The connection can also be made by bonding, for example by means of a thermally conductive adhesive.

The thermal aperture 18 forms a slit-shaped passage region arranged parallel to the active layer 14 for a heat flow 42 directed from the active zone 40 toward the underside of the laser diode 10. The slit-shaped passage region is arranged medially below the active zone 40 in the figure. Propagation of the heat flow 42 directed from the active zone 40 to the submount 30 in the lateral direction is suppressed by the thermal aperture 18 according to the invention, resulting in a largely parallel heat flow 42. The high thermal resistance of the thermal aperture 18 results in an increase in its local temperature (i.e., heating in the lateral regions) as more heat is generated by the active zone 40 with increasing output power. This results in a more uniform temperature distribution in the region below the active zone 40 between the central region (directly below the active zone) and the thermal aperture (the side regions). The formation of a thermal lens in this region is thus also suppressed, which can increase the beam quality during radiation emission.

The illustration further shows the horizontal distance dx between an outer edge of the active zone 40 and a nearest inner edge of the thermal aperture. Also shown is the vertical distance dy between the center of the active layer 14 and the thermal aperture 18. Also shown is the aperture thickness d_{block} of the thermal aperture 18 and the total layer thickness d of the p-doped semiconductor material 16.

The description applies accordingly to a thermal aperture 18 formed in the n-doped semiconductor material 12. In this case, a corresponding submount 30 above the active zone 40 could be thermally conductively connected to the n-side top of the laser diode 10 to suppress a lateral widening of an upwardly directed heat flow 42.

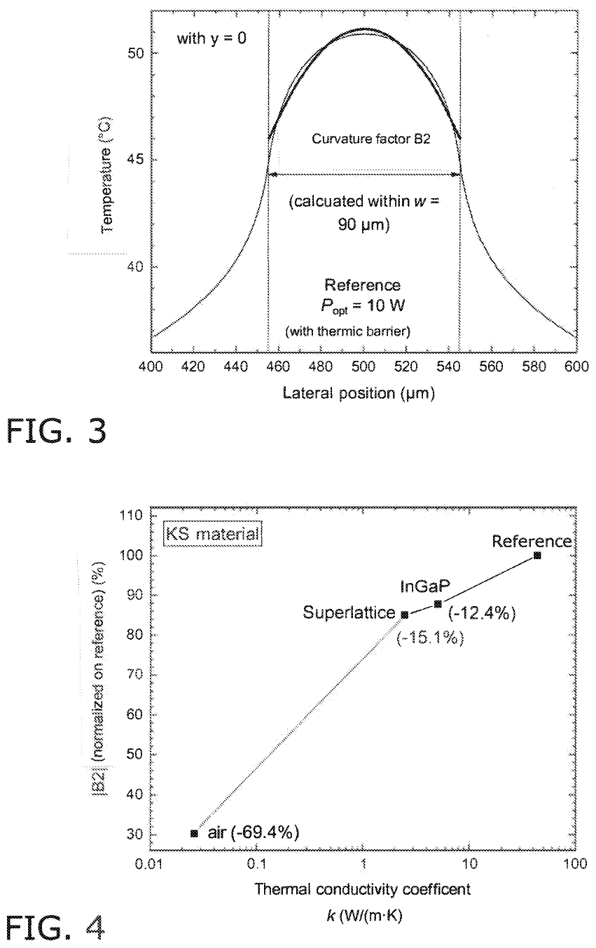

FIG. 3 shows a simulation of the temperature as a function of the lateral position (x-axis) within the active zone. The simulation was performed at a vertical position (y-axis) of y=0, i.e., in the center of the active layer, for a GaAs-based broad-area diode laser (BAL) with a stripe width w=90 μm (see M. Elattar et al, High-brightness broad-area diode lasers with enhanced self-aligned lateral structure, Semicond. Sci. Technol. 35, 095011 (2020)), which operates at an optical power Pₒₚₜ=10 W. The simulated BAL corresponds to the typical structure consisting of an active zone (AZ) between an n-doped and a p-doped semiconductor material. The p-doped semiconductor material consists of a AlₓGa₁₋ₓAs-waveguide layer (WL) grown on the AZ, followed by an AlₓGa₁₋ₓAs cladding layer (MS), and finally a GaAs contact layer (KS) on which a contact metal is subsequently deposited. The simulation (matching corresponding experimental results) includes a thermal barrier at the KS metal interface. The term thermal lens curvature factor B2 is the quadratic term of a quadratic fit of the obtained thermal profile (Rieprich, J. et al., Chip-carrier thermal barrier and its impact on lateral thermal lens profile and beam parameter product in high power broad area lasers, J. Appl. Phys. 123, 125703 (2018)), where a quadratic fit was performed in the simulation for the region within the stripe width w=90 μm. The exemplary conventional diode laser in the simulation shows that a thermal profile with a curved profile between about 45° C. at the edges and about 51° C. in the center of the broad strip is obtained.

FIG. 4 shows a simulation of the normalized thermal lens curvature factor |B2| as a function of the thermal conductivity coefficient k_{KS} of the p-contact layer. In the reference structure, the KS consists of GaAs (k_{KS}≈44 W/(m·K)). When GaAs is replaced by materials with lower thermal conductivity, such as InGaP (k_{block}≈5 W/(m·K)), InGaAsP (k_{block}≈5 W/(m·K)), an InGaP—InGaAsP superlattice (k_{block}≈2.5 W/(m·K)); see J. Piprek et al., Thermal conductivity reduction in GaAs—AlAs distributed Bragg reflectors, in IEEE Photon. Tech. Lett. 10, 81(1998)), or air (kₐᵢᵣ≈0.026 W/(m·K)) is substituted, the normalized thermal lens curvature factor |B2| is reduced, corresponding to a weakened thermal lens. This results in a smaller far-field angle and thus improved beam quality. Specifically, simulation showed that a 5% reduction in normalized thermal lens curvature factor |B2| can be achieved with a reduced thermal conductivity coefficient k_{KS}≈18 W/(m·K). A 10% reduction can be achieved with a thermal conductivity coefficient k_{KS}≈7 W/(m·K). For a 15% reduction, the thermal conductivity coefficient should be k_{KS}≈2.5 W/(m·K).

FIG. 5 shows a simulation of the normalized thermal lens curvature factor |B2| as a function of the aperture thickness d_{block}. When layers of GaAs (KS) or AlₓGa₁₋ₓAs (MS, WL) are replaced by InGaP (low thermal conductivity coefficient k), d he normalized thermal lens curvature factor |B2| is reduced, corresponding to the formation of a weakened thermal lens. This results in a smaller far-field angle and thus improved beam quality. In particular, the simulation showed that a 5% reduction in the normalized thermal lens curvature factor |B2| can be achieved with an aperture thickness d_{block}≈688 nm. A 10% reduction can be achieved with an aperture thickness d_{block}≈1375 nm.

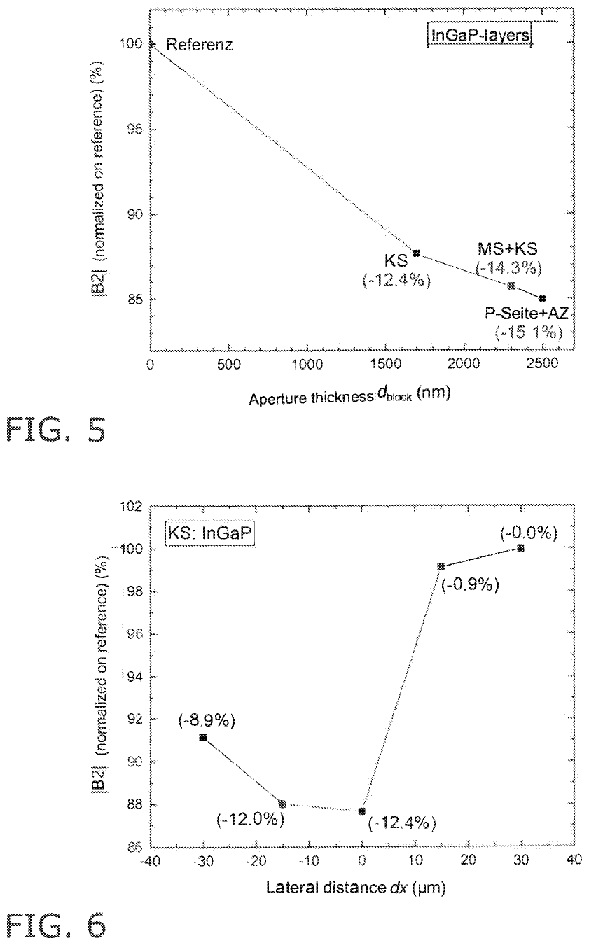

FIG. 6 shows a simulation of the normalized thermal lens curvature factor |B2| as a function of the lateral distance dx. The KS was assumed here to consist of InGaP. It can be observed that the thermal apertures can reduce the thermal lens curvature factor |B2| most effectively when dx=0, i.e., the thermally particularly conductive slit-shaped passage region below the active zone aligns perfectly medially with the laser stripe.

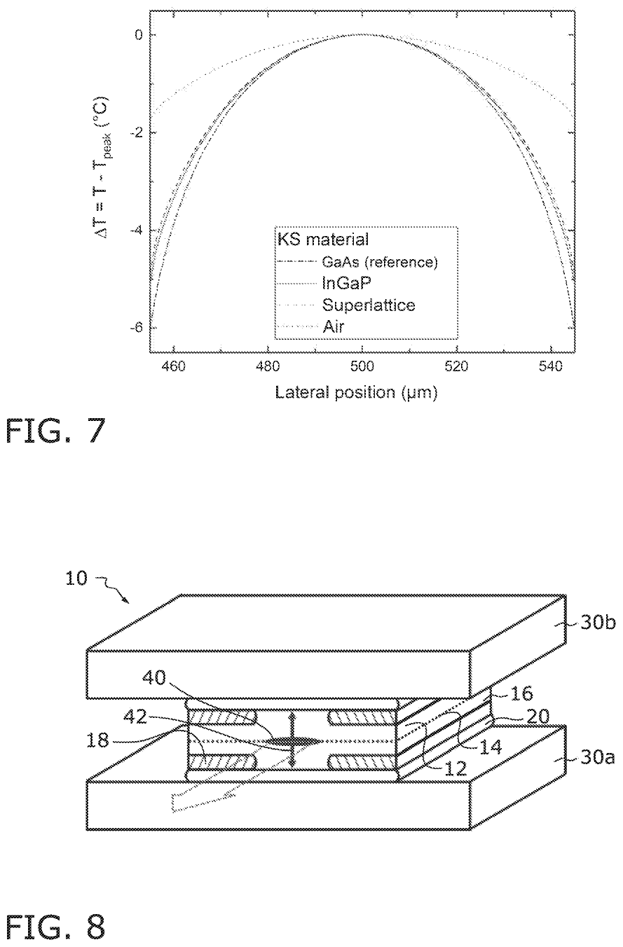

FIG. 7 shows a simulation of the temperature difference ΔT between the temperature T as a function of lateral position (x-axis) and the peak temperature Tₚₑₐₖ at position x=0 for structures with the KS material shown in FIG. 4. The curve shows the reduction of the curvature of the thermal lens when GaAs is replaced by materials with lower thermal conductivity.

FIG. 8 shows a schematic illustration of an exemplary second embodiment of a laser diode according to the invention with two thermal apertures. The laser diode 10 shown corresponds in principle to a first embodiment of a laser diode 10 according to the invention with a thermal aperture 18 shown in FIG. 2. The individual reference numerals and their respective assignment to the individual features therefore apply accordingly. In contrast to the illustration in FIG. 2, however, a structure with thermal apertures 18 according to the invention is shown here both in the p-doped semiconductor material 16 below the active layer 14 and in the n-doped semiconductor material 12 above the active layer 14. A first submount 30a is thermally conductively connected to an underside of the laser diode 10 below the active zone 40. Furthermore, a second submount 30b is thermally conductively connected above the active zone 40 to a top of the laser diode 10. Cooling can thus take place on both sides of the laser diode 10, whereby a lateral widening of the heat flow 42 both to the top and to the underside of the laser diode 10 can be effectively suppressed by thermal apertures 18. Such an embodiment is advantageous when the laser diode 10 is mounted for double-sided cooling, i.e., when heat extraction can occur to both sides of the laser diode 10. The laser diode shown is symmetrical with respect to the active layer 14.

From the foregoing, it will be appreciated that specific embodiments of the invention have been described herein for purposes of illustration, but that various modifications may be made without deviating from the scope of the invention. Accordingly, the invention is not limited except as by the appended claims.

What is claimed is:

1. A laser diode, comprising:
an active layer formed between an n-doped semiconductor material and a p-doped semiconductor material, wherein the active layer forms an active zone with a width w along a longitudinal axis for generating electromagnetic radiation;
wherein in the p-doped or n-doped semiconductor material a thermal aperture formed in a layer shape with a thermal conductivity coefficient k_{block} smaller than a thermal conductivity coefficient k_{bulk} of the respective doped semiconductor material is formed for spatially selective heat transport from the active zone to a side of the respective doped semiconductor material opposite to the active layer (14).

2. The laser diode of claim 1, wherein the thermal aperture consists of the same semiconductor material as the respective doped semiconductor material.

3. The laser diode of claim 1, wherein the thermal aperture is formed of periodically alternating materials.

4. The laser diode of claim 1, wherein the thermal aperture forms a slit-shaped passage region, arranged parallel to the active layer, for a heat flow directed from the active zone towards an outer side of the laser diode.

5. The laser diode of claim 4, wherein the slit-shaped passage region is arranged medially with respect to the active zone.

6. The laser diode of claim 1, wherein the lateral distance dx between an outer edge of the active zone and a nearest inner edge of the thermal aperture is −w/6≤dx≤+w/6.

7. The laser diode of claim 1, wherein the vertical distance dy between the center of the active layer and the top of the thermal aperture is 0 μm≤dy≤1 μm.

8. The laser diode of claim 1, wherein the thermal aperture has an aperture thickness d_{block} between 0.3 μm and 3 μm.

9. The laser diode of claim 1, wherein the thermal conductivity coefficient k_{block} is at most 30% of the corresponding thermal conductivity coefficient k_{bulk}.

10. The laser diode of claim 1, wherein a thermal aperture formed in a layer shape is formed in the n-doped semiconductor material and a thermal aperture formed in a layer shape is formed in the p-doped semiconductor material.
